(19) United States
(12) Patent Application Publication
(10) Pub. No.: US 2010/0306582 A1
(43) Pub. Date: Dec. 2, 2010

(54) METHOD OF OPERATING NONVOLATILE MEMORY DEVICE

(76) Inventors: Jung Chul Han, Gyeonggi-do (KR); Byoung Kwan Jeong, Jeollabuk-do (KR)

Correspondence Address: IP & T GROUP LLP, 7700 Little River Turnpike, Suite 207, Annandale, VA, 22003, US

(21) Appl. No.: 12/779,252

(22) Filed: May 13, 2010

(30) Foreign Application Priority Data
May 29, 2009 (KR) 10-2009-0047824

(51) Int. Cl. G06F 11/00; G11C 29/00

(52) U.S. Cl. 714/8; 714/722; 714/718; 714/E11.03; 714/E11.085

(57) ABSTRACT

A method of operating a nonvolatile memory device includes performing a program operation on memory cells included in a selected page, checking whether a verification operation for the programmed memory cells is passed or failed by performing the verification operation, counting a number of error bits for the selected page, if the verification operation is failed, performing an error checking and correction (ECC) algorithm using an error correction circuit, if the counted number of error bits is less than or equal to a number of correctable bits, and storing the counted number of error bits in a specific one of a plurality of memory blocks.

### CROSS-REFERENCE TO RELATED APPLICATION

Priority to Korean patent application number 10-2009-0047824 filed on May 29, 2009, the entire disclosure of which is incorporated by reference herein, is claimed.

### BACKGROUND

Exemplary embodiments relate to a method of operating a nonvolatile memory device.

In recent years, there has been an increasing demand for nonvolatile memory devices which can be electrically programmed and erased and which do not require the refresh function of rewriting data at specific intervals.

A NAND flash memory device of nonvolatile memory devices uses a page buffer in order to store a high capacity of information within a short period of time and to verify whether program and erase operations have been normally performed. A known page buffer consists of a single register in order to temporarily store data, but recently includes a dual register in order to increase the speed of data programming.

The operations of the nonvolatile memory device can be classified into a program operation for storing data in a memory cell array, a read operation for reading data stored in the memory cell array, and an erase operation for erasing data stored in the memory cell array.

In the nonvolatile memory device, the program operation is performed through a number of program loops. Each of the program loops includes a program period and a verification period. The program loop is repeatedly performed within a maximum number of program loops until all the selected memory cells are programmed. If the program operation is treated as a program fail within the maximum number of program loops, a memory block treated as a program fail is classified as a bad block. Such classification as the bad block is performed irrespective of the number of error bits. If the number of error bits is determined to be within the number of correctable bits by an error checking and correction (ECC) circuit, the error bits can be corrected by the ECC circuit when a read operation is performed.

Meanwhile, in known memory devices, if a memory block is classified as a bad block, it means that a fail has occurred in the erase operation, the program operation, or the read operation. If a fail occurs in a block during these operations, a controller treats the corresponding memory block as a bad block. If a fail occurs in a block during the erase operation, the corresponding memory block is classified as a bad block and considered as not having been used. In the case in which a block is treated as a bad block because a fail occurs in the memory block during the program operation or the read operation, however, there is a need for a copyback operation for moving data, stored in the bad block, to another memory block. The process of processing a bad block, as described above, requires as much time as the time taken for performing a read operation and a program operation on one block.

In a common read operation, the properties of a memory cell are deteriorated with an increased use of the memory cell. If the number of error bits exceeds a range correctable by the ECC circuit, a corresponding memory block is treated as a bad block, and so the frequency of bad blocks is relatively low during the read operation. However, in a common program operation, a fail occurs because of a small number of memory cells with a lowered program speed, and so the frequency of bad blocks is high as compared with the read operation.

If a fail occurs during the program operation of a nonvolatile memory device, a corresponding memory block is treated as a bad block. The corresponding memory block is managed so that it is not used, which may increase the time that it takes to program one page. If the bad block is generated as described above, the time taken for the nonvolatile memory device to be operated is also increased, leading to a reduction in available memory space. Accordingly, there is a need for a method of processing a fail occurring during the operation of a nonvolatile memory device while reducing the occurrence of a bad block during the operation.

### BRIEF SUMMARY

Exemplary embodiments relate to a method of managing a bad block which is generated during a program operation.

A method of operating a nonvolatile memory device according to an aspect of the present disclosure includes performing a program operation on memory cells included in a selected page, checking whether a verification operation for the programmed memory cells is passed or failed by performing the verification operation, counting a number of error bits for the selected page, if the verification operation is failed, performing an error checking and correction (ECC) algorithm using an error correction circuit, if the counted number of error bits is less than or equal to a number of correctable bits, and storing the counted number of error bits in a specific one of a plurality of memory blocks.

The method may further include determining the program operation on a selected memory block, including the selected page, to be a program fail and treating the selected memory block as a bad block, if the number of error bits is more than the number of bits correctable by the error correction circuit.

Counting the number of error bits for the selected page comprises performing the verification operation a certain number of times or more and then counting the number of error bits for the selected page.

The method may further include selecting a memory block in which data will be stored when a program command signal is received, before performing the program operation on the memory cells of the selected page.

Selecting the memory block in which data will be stored comprises a wear leveling process of checking the number of error bits for each of the memory blocks and selecting a memory block, having a least number of error bits, as the specific memory block in which data will be stored.

The method may further include storing the cumulative number of program and erase operations (P/E cycles) for each memory block in the specific memory block.

Selecting the memory block in which data will be stored may include a wear leveling process of checking the cumulative number of P/E cycles for each of the memory blocks and selecting a memory block, having a least cumulative number of P/E cycles, as the specific memory block in which data will be stored.

The cumulative number of P/E cycles for each of the memory blocks may be stored in the specific memory block.

Treating the selected memory block as a bad block may include designating the selected memory block as the bad block, updating a bad block table in which bad block information is stored, and copying data, stored in the selected memory block, to another memory block.

Updating the bad block table in which bad block information is stored may include storing an address and the number of error bits of the selected memory block in the bad block table included in the specific memory block.

The method may further include performing a program operation on a page of said another memory block corresponding to an address of the selected page, after copying data, stored in the selected memory block, to said another memory block.

The method may further include determining whether error bits have occurred in a page neighboring the selected page, if the counted number of error bits is less than or equal to the number of correctable bits, but is more than a certain number of error bits, if, as a result of the determination, error bits are determined to have occurred in the neighboring page, counting and storing a number of error bits for the neighboring page, and determining the program operation on the memory block, including the neighboring page, to be a program fail and treating the memory block as a bad block, if the counted number of error bits exceeds the number of correctable bits.

A method of operating a nonvolatile memory device according to another aspect of the present disclosure includes inputting a program command, selecting a memory block in which data will be stored, from among a plurality of memory blocks, based on a number of error bits counted in each of the memory blocks, and performing a program operation on memory cells included in a selected page of the selected memory block.

Selecting the memory block in which data will be stored may include selecting a memory block having a least number of error bits from among the plurality of memory blocks.

The method may further include storing the number of error bits, counted in each of the memory blocks, in the selected memory block.

Selecting the memory block in which data will be stored may include a method of selecting the memory block in which data will be stored based on the cumulative number of P/E cycles for each of the memory blocks.

The method of selecting the memory block in which data will be stored based on the cumulative number of P/E cycles for each of the memory blocks may include selecting a memory block having a least cumulative number of P/E cycles from among the plurality of memory blocks.

The cumulative number of P/E cycles for each of the memory blocks may be stored in one of the memory blocks.

### BRIEF DESCRIPTION OF THE DRAWINGS

FIGS. 1A and 1B are block diagrams of a host system and a nonvolatile memory device according to an exemplary embodiment of the present disclosure;

FIG. 2 is a block diagram showing the internal construction of the nonvolatile memory device according to an exemplary embodiment of the present disclosure;

FIG. 3 is a diagram showing the structure of the memory cell array of the nonvolatile memory device according to an exemplary embodiment of the present disclosure;

FIG. 4 is a flowchart illustrating a method of operating the nonvolatile memory device according to an exemplary embodiment of the present disclosure; and

FIG. 5 is a flowchart illustrating a method of operating the nonvolatile memory device according to another exemplary embodiment of the present disclosure.

### DESCRIPTION OF EMBODIMENTS

Hereinafter, some exemplary embodiments of the present disclosure will be described in detail with reference to the accompanying drawings. The figures are provided to allow those having ordinary skill in the art to understand the scope of the embodiments of the disclosure.

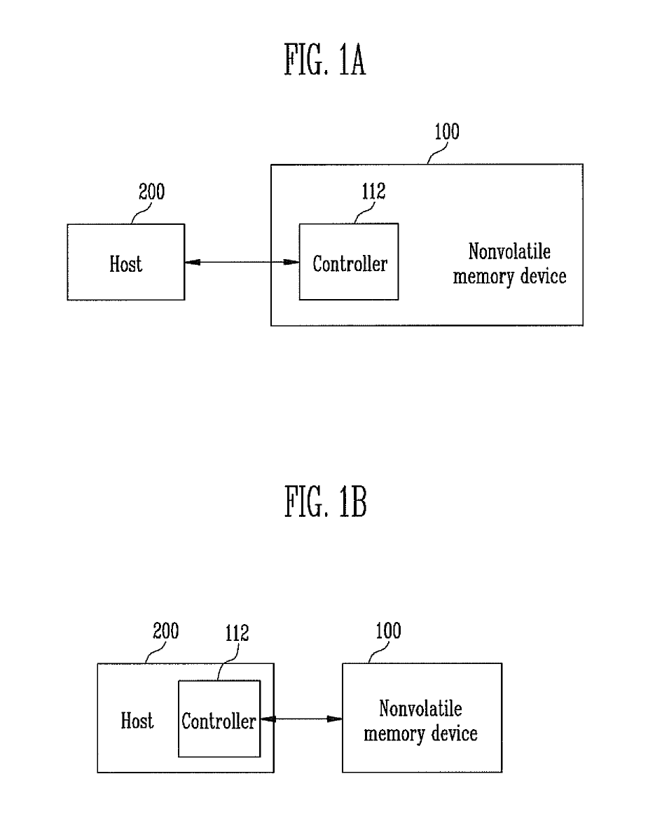

FIGS. 1A and 1B are block diagrams of a host system and a nonvolatile memory device according to an exemplary embodiment of the present disclosure. FIG. 1A shows an example in which a controller 112 is included in the nonvolatile memory device 100. FIG. 1B shows an example in which the controller 112 is included in a host system 200. As described above, in the present disclosure, the controller 112 may be included in the nonvolatile memory device 100 or the host system 200.

The host system 200 is a kind of application device for storing data in the nonvolatile memory device 100, reading data stored in the nonvolatile memory device 100, and using the read data. For example, the host system 200 can include a variety of application devices, such as MP3 players, digital cameras, mobile phones, and navigators which use the nonvolatile memory device 100 as a principle storage device.

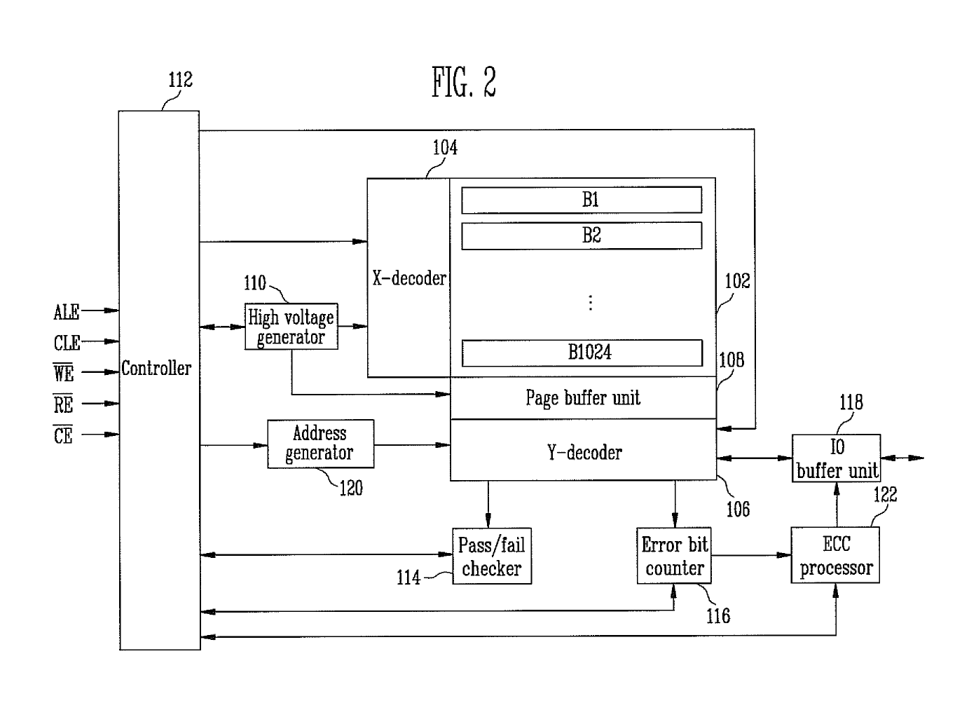

FIG. 2 is a block diagram showing the internal construction of the nonvolatile memory device according to an exemplary embodiment of the present disclosure.

The nonvolatile memory device 100 includes a memory cell array 102, an X decoder 104, a Y decoder 106, a page buffer unit 108, a high voltage generator 110, the controller 112, a pass/fail checker 114, an error bit counter 116, an IO buffer unit 118, an address generator 120, and an ECC processor 122.

The memory cell array 102 includes a number of memory blocks. In the exemplary embodiment of FIG. 2, it is assumed that the memory cell array 102 includes 1024 memory blocks B1-B1024. In the present disclosure, bad block-related information, including the number of error bits for every block and the cumulative number of program and erase operations (hereinafter referred to as ‘P/E cycles’) for every block, can be stored in a specific one of the memory blocks included in the memory cell array 102. For example, the bad block information may be stored in the 1024^{th} memory block B1024.

The controller 112 controls the nonvolatile memory device 100 and generates a program command signal, an erase command signal, and a read command signal in response to signals transmitted and received through the TO buffer unit 118. For example, when a chip enable signal /CE is enabled and a write enable signal /WE is toggled, the controller 112 can receive the command signal through the IO buffer unit 118. In response to the command signal, the controller 112 generates a program command, an erase command, or a read command. Furthermore, the controller 112 sends the command signal in response to a command latch enable signal CLE and sends an address signal in response to an address latch enable signal ALE.

The high voltage generator 110 generates bias voltages in response to the program command, the erase command, or the read command generated by the controller 112, and supplies them to the page buffer unit 108, the X decoder 104, and so on.

The address generator 120 is controlled by the controller 112 and configured to generate a column address signal.

The X decoder 104 supplies the bias voltages, supplied from the high voltage generator 110, to one of the memory blocks of the memory cell array 102 in response to a row address signal generated by the controller 112.

The Y decoder 106 supplies a data signal to the page buffer unit 108 in response to a column address signal generated by the address generator 120. Furthermore, the Y decoder 106 functions to output data, stored in the page buffer unit 108, through the IO buffer unit 118 during a read operation.

The page buffer unit 108 includes a plurality of page buffers. Each of the page buffers stores data signals received through the IO buffer unit 118 and the Y decoder 106 and outputs them to bit lines coupled to the memory blocks of the memory cell array 102. Furthermore, the page buffer unit 108 stores data read from the memory cell array 102 during a read operation, and outputs the data externally through the Y decoder 106 and the IO buffer unit 118.

The pass/fail checker 114 checks whether a program operation is passed based on data read from memory cells during a verification operation. For example, the pass/fail checker 114 can compare data stored in programmed memory cells and data to be programmed. If, as a result of the comparison, both data are identical, the pass/fail checker 114 determines that a program operation is passed. If, as a result of the comparison, both data are not identical, the pass/fail checker 114 determines that the program operation is failed.

The error bit counter 116 counts the number of error bits from among data read from programmed memory cells.

The ECC processor 122 corrects error data received from the Y decoder 106 and outputs error-corrected data.

In the present disclosure, the controller 112 compares the number of error bits, outputted from the error bit counter 116, and the number of bits correctable by the ECC processor 122. If, as a result of the comparison, the number of error bits is less than or equal to the number of correctable bits, the controller 112 treats the program operation as a program pass.

As described above, the nonvolatile memory device of the present disclosure can use an ECC algorithm. In nonvolatile memory devices to which the ECC algorithm is applied, data are stored using the ECC algorithm, and when the data are read, error data are corrected using the ECC algorithm. Here, the capability to process the ECC algorithm used in the nonvolatile memory device is preset according to the processing capability of a processor used in the controller 112. For example, in the case in which an ECC algorithm capable of processing ‘n’ (where ‘n’ is a positive integer) error bits is used, if ‘n’ error bits or less are generated, the corresponding error bits can be corrected using the ECC algorithm. If more than ‘n’ error bits are generated, the corresponding error bits cannot be corrected using the ECC algorithm. The number of bits correctable by the ECC algorithm is used as the number of allowed error bits. That is, if the number of fail bits is the number of correctable bits or less, error correction is possible using the ECC algorithm. Accordingly, the program operation on a page including a corresponding memory cell is treated as a program pass although it includes error bits.

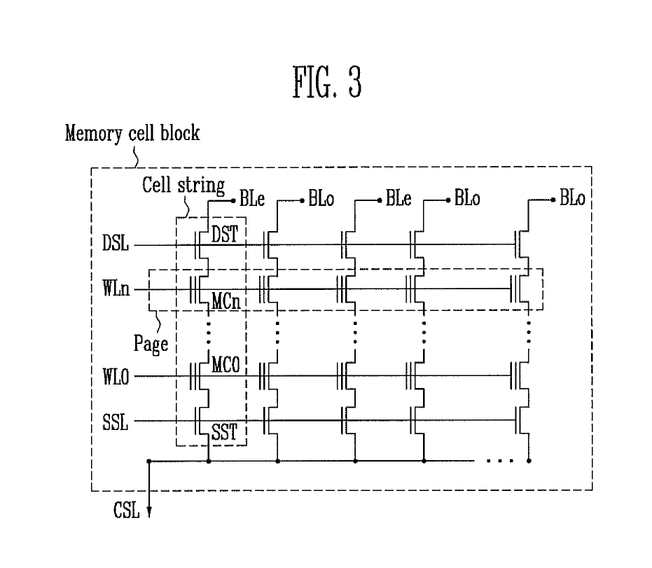

FIG. 3 is a diagram showing the structure of the memory cell array of the nonvolatile memory device according to an exemplary embodiment of the present disclosure. Although the memory cell array includes a number of the memory cell blocks, only one memory cell block is illustrated in FIG. 3, for the sake of convenience.

The memory cell array includes a number of the memory cell blocks. Each of the memory cell blocks includes a number of cell strings coupled to respective bit lines BLe, BLo and coupled in parallel to a common source line CSL. Each of the cell strings includes memory cells MC0 to MCn for storing data, a drain select transistor DST coupled between the bit line BLe, BLo and the memory cells MC0 to MCn, and a source select transistor SST coupled between the memory cells MC0 to MCn and the common source line CSL. The gates of the drain select transistors DST, belonging to different cell strings, are coupled together, thus forming a drain selection line DSL. The gates of the source select transistors SST, belonging to different cell strings, are coupled together, thus forming a source selection line SSL. The gates of the memory cells, belonging to different cell strings, are coupled together, thus forming respective word lines WL0 to WLn. One word line WL is referred to as a page.

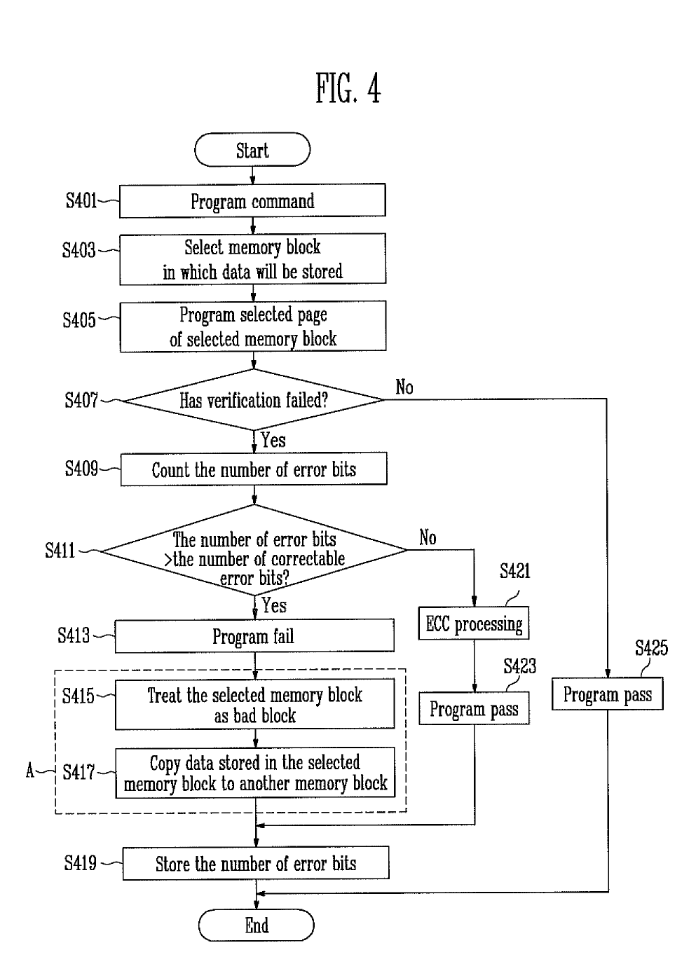

FIG. 4 is a flowchart illustrating a method of operating the nonvolatile memory device according to an exemplary embodiment of the present disclosure.

Referring to FIGS. 2 and 4, a program operation command for storing data in the memory cells is inputted to the controller 112 through the JO buffer unit 118 at step S401. Next, the controller 112 selects a memory block in which the data will be stored at step S403. In the present disclosure, a method of selecting the memory block in which data will be stored at step S403 is described later.

The controller 112 performs a program operation on memory cells included in a selected page of the selected memory block at step S405. It is checked whether a verification operation is passed or failed by performing the verification operation on the programmed memory cells at step S407. Here, the pass/fail checker 114 checks the verification pass or fail. If, as a result of the check, the verification operation is not failed, the program operation on the corresponding page is treated as a program pass at step S425. For example, if each of memory cells in which program data (e.g., data ‘0’) will be stored has a threshold voltage higher than a target voltage, a verification operation for the memory cells is passed, and so the program operation on the memory cells is treated as a program pass.

However, if, as a result of the check at step S407, the verification operation is failed, the error bit counter 116 counts the number of error bits for the failed page at step S409. In other words, if any one of the memory cells in which the program data will be stored has a threshold voltage less than the target voltage, the pass/fail checker 114 determines that the verification operation is failed, and the error bit counter 116 keeps count of the number of error bits occurring in the failed page.

The controller 112 determines whether the counted number of error bits is more than the number of bits correctable by the ECC processor 122 at step S411. If, as a result of the determination, the counted number of error bits is determined to exceed the number of correctable bits, the controller 112 determines the program operation on the corresponding page to be a program fail at step S413. In an exemplary embodiment of this disclosure, if the counted number of error bits for a selected page exceeds the number of correctable bits, it is checked whether the number of program loops performed equals a maximum number of allowed loops. If the number of program loops performed is less than the maximum number of allowed loops, a program operation may be performed on the selected page again. If the number of program loops performed equals the maximum number of allowed loops, the program operation on the selected page can be determined to be a program fail.

After the step S413, the method proceeds to process (A) in which the selected memory block, including the failed page in which the program operation is determined to be a program fail, is treated as a bad block. Steps of processing the corresponding memory block as a bad block are described in detail below. First, the corresponding memory block, including the failed page, is designated as a bad block at step S415. Next, data stored in the corresponding memory block is copied to another memory block at step S417. After the copyback operation, a program operation is performed on the memory block to which the data are copied. Here, the program operation is performed on a page corresponding to an address of the failed page.

Next, the number of error bits counted in the selected memory block is stored in one of the memory blocks at step S419. For example, the number of error bits can be stored in the 1024^{th} memory block B1024 shown in FIG. 2. To add an address of the bad block to bad block information, the bad block table of the corresponding memory block in which the bad block information is stored is updated. For example, assuming that the memory block in which the bad block information is stored is the 1024^{th} memory block B1024, the bad block table of the 1024^{th} memory block B1024 is updated.

Meanwhile, if, as a result of the determination at step S411, the counted number of error bits is determined to be the number of correctable bits or less, the ECC processor 122 corrects the error bits by performing an ECC algorithm using an FCC circuit at step S421. After the error bits are corrected by the ECC processor 122, the program operation on the corresponding memory block including the error-corrected bits is treated as a program pass at step S423. Next, the number of error bits counted in the corresponding memory block is stored in one of the memory blocks at step S419. The number of error bits for each of the memory blocks, stored in the memory block assigned to store the number of error bits counted, can be used for wear leveling methods of selecting an appropriate memory block in which data will be stored in response to a program command. In other words, the numbers of error bits for the memory blocks, stored in the memory block assigned to store the number of error bits counted, can be compared with each other, and a memory block having the least number of error bits can be selected as a memory block in which data will be stored.

In an exemplary embodiment of this disclosure, for example, if, as a result of the determination at step S411, the counted number of error bits is less than or equal to the number of correctable bits, but is a reference value or more, a read operation can be performed on a page adjacent to the selected page, and the number of error bits for the adjacent page can be counted. If the counted number of error bits for the adjacent page exceeds the number of correctable bits, a program operation on a corresponding memory block, including the adjacent page, is determined to be a program fail, and therefore, the corresponding memory block is treated as a bad block. However, if the counted number of error bits for the adjacent page is less than or equal to the number of correctable bits, the ECC processor 122 corrects the error bits by performing an ECC algorithm using an ECC circuit, and so the program operation on the corresponding memory block is determined to be a program pass. The reason why the read operation is performed on the page adjacent to the selected page and the ECC algorithm is performed on the error bits is as follows. If the number of error bits counted in the selected page is the reference value or more although it is the number of correctable bits or less, there is a high possibility that the corresponding memory block may have an error during a program operation. To prevent this problem, it is checked whether a program operation has normally been performed on the page adjacent to the selected page.

In the present disclosure, the bad block information stored in an assigned memory block (e.g., the 1024^{th} memory block B1024) can be used at step S403, which is described in detail below.

The method of selecting a memory block in which program data will be stored at step S403 is described in detail below. According to an exemplary embodiment of the present disclosure, the following two methods of selecting a memory block in which program data will be stored at step S403 are proposed.

The first method adopts a wear leveling method of checking the number of error bits for each memory block, and selecting a memory block with the least number of error bits from among memory blocks in which program data are not stored. For example, referring to FIG. 2, the number of error bits for each of the memory blocks, except for memory blocks in which data are stored and the memory block (e.g., the 1024^{th} memory block B1024) in which the bad block information is stored, from among the memory blocks B1-B1024 included in the memory cell array 102, is checked. As a result of the check, a memory block with the least number of error bits is selected as a memory block in which program data will be stored. In this case, the number of error bits for each memory block can be checked using the memory block (e.g., the 1024^{th} memory block B1024) in which the bad block information, including the number of error bits for each memory block, is stored. In general, if a memory block has a relatively large number of error bits, it has a higher possibility of having additional error bits. For this reason, a memory block with the least number of error bits is selected as a memory block in which program data will be stored. In this case, the possibility that error bits will occur can be reduced.

In general, memory blocks having many error bits in a previous program operation are more likely to have additional error bits in a subsequent program operation. If the number of error bits is relatively high, the operating speed becomes slow, and so a possibility that the corresponding memory block can be treated as a bad block is increased. For this reason, a memory block with the least number of error bits is selected as a memory block in which program data will be stored. In this case, a point in time at which a bad block is determined can be postponed, and the operating speed can be improved.

The second method adopts a wear leveling method of checking the cumulative number of P/E cycles for each memory block and selecting a memory block with the least cumulative number of P/E cycles from among memory blocks in which data are not stored to be a memory block in which program data will be stored. In other words, referring to FIG. 2, the cumulative number of P/E cycles for each memory block, except for memory blocks in which data are stored and the memory block (e.g., the 1024^{th} memory block B1024) in which the bad block information is stored, from among the memory blocks B1-B1024 included in the memory cell array 102, is checked. As a result of the check, a memory block with the least cumulative number of P/E cycles is selected as a memory block in which program data will be stored. In this case, the cumulative number of P/E cycles for each memory block can be checked using the memory block (e.g., the 1024^{th} memory block B1024) in which the bad block information, including the cumulative number of P/E cycles for each memory block, is stored.

In general, if the program and erase operations are repeated, the properties of a memory cell are deteriorated, which results in a higher possibility of a memory block having additional error bits. For this reason, a memory block with the least cumulative number of P/E cycles is selected as a memory block in which program data will be stored. In the present disclosure, the two kinds of methods are proposed as the method of selecting a memory block. It is, however, to be noted that the above methods are only illustrative, and many other methods are possible.

As described above, in the present disclosure, bad block information, including the number of error bits for each memory block and the cumulative number of P/E cycles for each memory block, can be stored in one of the memory blocks included in the memory cell array 102. The reason why the bad block information is stored in the memory block is that information stored in a memory block can be safely retained because it is not deleted unless an additional erase operation is performed.

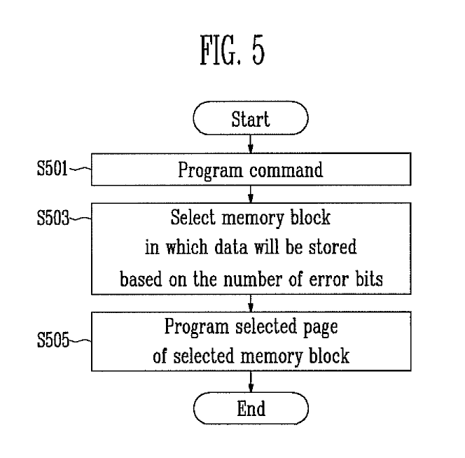

FIG. 5 is a flowchart illustrating a method of operating the nonvolatile memory device according to another exemplary embodiment of the present disclosure.

After a program command is received through the IO buffer unit 118 at step S501, the controller 112 selects a memory block in which program data will be stored based on the number of error bits for each memory block at step S503. In an exemplary embodiment of this disclosure, at step S503, a memory block with the least number of error bits can be selected from among a number of memory blocks. Here, the number of error bits for each memory block can be stored in one of the memory blocks. For example, referring to FIG. 2, the number of error bits for each memory block can be stored in the 1024^{th} memory block B1024.

The step S503 can further include a method of selecting a memory block in which program data will be stored based on the cumulative number of P/E cycles for each memory block. According to an exemplary embodiment of this disclosure, in the method of selecting a memory block in which program data will be stored based on the cumulative number of P/E cycles for each memory block, a memory block with the least cumulative number of P/E cycles can be selected from among a number of memory blocks. In this case, the cumulative number of P/E cycles for each memory block can be stored in one of the memory blocks.

Moreover, both the method of selecting a memory block in which program data will be stored based on the number of error bits occurred in each memory block and the method of selecting a memory block in which program data will be stored based on the cumulative number of P/E cycles for each memory block can be used at step S503. In other words, the method of selecting a memory block based on the number of error bits can be primarily used, and the method of selecting a memory block based on the cumulative number of P/E cycles can be complementarily used. For example, if, as a result of selecting a memory block based on the number of error bits, multiple memory blocks are selected, then a memory block with the least cumulative number of P/E cycles can be selected from among the multiple memory blocks.

Next, the controller 112 performs a program operation on the memory cells of a selected page included in the selected memory block at step S505.

According to the present disclosure, in managing a bad block of a nonvolatile memory device, an ECC processing is performed based on the number of error bits. Accordingly, bad blocks can be more efficiently managed, and so the lifespan of the nonvolatile memory device can be increased.

Furthermore, a memory block in which program data will be stored is selected using the wear leveling method based on the number of error bits and the wear leveling method based on the cumulative number of P/E cycles. Accordingly, a possibility that a memory block is erroneously treated as a bad block during a program operation can be reduced, and so a reduction in the effective capacity of storing data can be prevented. Further, the yield can be enhanced because the time that it takes to perform a program operation can be reduced.

What is claimed is:

1. A method of operating a nonvolatile memory device, the method comprising:
performing a program operation on memory cells included in a selected page;
checking whether a verification operation for the programmed memory cells is passed or failed by performing the verification operation;
counting a number of error bits for the selected page, if the verification operation is failed;
performing an error checking and correction (ECC) algorithm using an error correction circuit, if the counted number of error bits is less than or equal to a number of correctable bits; and
storing the counted number of error bits in a specific one of a plurality of memory blocks.

2. The method of claim 1, further comprising, determining the program operation on a selected memory block, including the selected page, to be a program fail and treating the selected memory block as a bad block, if the number of error bits is more than the number of bits correctable by the error correction circuit.

3. The method of claim 1, wherein the counting of the number of error bits for the selected page comprises performing the verification operation a certain number of times or more and then counting the number of error bits for the selected page.

4. The method of claim 1, further comprising selecting a memory block in which data will be stored when a program command signal is received, before performing the program operation on the memory cells of the selected page.

5. The method of claim 4, wherein the selecting of the memory block in which data will be stored comprises a wear leveling process of checking the number of error bits for each of the memory blocks and selecting a memory block, having a least number of error bits, as the specific memory block in which data will be stored.

6. The method of claim 4, further comprising storing a cumulative number of P/E cycles for each memory block in the specific memory block.

7. The method of claim 6, wherein the selecting of the memory block in which data will be stored comprises a wear leveling process of checking the cumulative number of P/E cycles for each of the memory blocks and selecting a memory block, having a least cumulative number of P/E cycles, as the specific memory block in which data will be stored.

8. The method of claim 7, wherein the cumulative number of P/E cycles for each of the memory blocks is stored in the specific memory block.

9. The method of claim 2, wherein the treating of the selected memory block as a bad block comprises:
designating the selected memory block as the bad block;
updating a bad block table in which bad block information is stored; and
copying data, stored in the selected memory block, to another memory block.

10. The method of claim 9, wherein the updating of the bad block table in which bad block information is stored comprises storing an address and the number of error bits of the selected memory block in the bad block table included in the specific memory block.

11. The method of claim 9, further comprising performing a program operation on a page of said another memory block corresponding to an address of the selected page, after copying data, stored in the selected memory block, to said another memory block.

12. The method of claim 1, further comprising:
determining whether error bits have occurred in a page neighboring the selected page, if the counted number of error bits is less than or equal to the number of correctable bits, but is more than a certain number of error bits;
if, as a result of the determination, error bits are determined to have occurred in the neighboring page, counting and storing a number of error bits for the neighboring page; and
determining the program operation on the memory block, including the neighboring page, to be a program fail and treating the memory block as a bad block, if the counted number of error bits exceeds the number of correctable bits.

13. A method of operating a nonvolatile memory device, the method comprising:
inputting a program command;
selecting a memory block in which data will be stored, from among a plurality of memory blocks, based on a number of error bits counted in each of the memory blocks; and
performing a program operation on memory cells included in a selected page of the selected memory block.

14. The method of claim 13, wherein the selecting of the memory block in which data will be stored comprises selecting a memory block having a least number of error bits from among the plurality of memory blocks.

15. The method of claim 13, further comprising storing the number of error bits, counted in each of the memory blocks, in the selected memory block.

16. The method of claim 13, wherein the selecting of the memory block in which data will be stored comprises selecting the memory block in which data will be stored based on a cumulative number of P/E cycles for each of the memory blocks.

17. The method of claim 16, wherein the selecting of the memory block in which data will be stored based on the cumulative number of P/E cycles for each of the memory blocks comprises selecting a memory block having a least cumulative number of P/E cycles from among the plurality of memory blocks.

18. The method of claim 16, wherein the cumulative number of P/E cycles for each of the memory blocks is stored in one of the memory blocks.
